(19) United States
(12) Patent Application Publication
(10) Pub. No.: US 2013/0037804 A1
(43) Pub. Date: Feb. 14, 2013

(54) DISPLAY DEVICE

(71) Applicants: Jae-Seob LEE, Yongin-city (KR); Chang-Yong JEONG, Yongin-city (KR); Yong-Hwan PARK, Yongin-city (KR); Kyung-Mi KWON, Yongin-city (KR)

(72) Inventors: Jae-Seob LEE, Yongin-city (KR); Chang-Yong JEONG, Yongin-city (KR); Yong-Hwan PARK, Yongin-city (KR); Kyung-Mi KWON, Yongin-city (KR)

(21) Appl. No.: 13/429,259

(22) Filed: Mar. 23, 2012

(30) Foreign Application Priority Data
Aug. 10, 2011 (KR) 10-2011-0079673

(51) Int. Cl. H01L 29/04

(52) U.S. Cl. 257/49; 257/52; 257/75; 257/E29.003

(57) ABSTRACT

A display device includes: a base film including plastic; an active layer on the base film, the active layer including a polysilicon layer formed by crystallizing an amorphous silicon layer using a laser; a barrier layer between the active layer and the base film; and a laser absorption layer between the barrier layer and the active layer.

### CROSS-REFERENCE TO RELATED APPLICATION

This application claims priority to and the benefit of Korean Patent Application No. 10-2011-0079673 filed in the Korean Intellectual Property Office on Aug. 10, 2011, the entire content of which is incorporated herein by reference.

### BACKGROUND

1. Field

The described technology relates generally to a display device. More particularly, the described technology relates to a display device using a base film including plastic.

2. Description of Related Art

Recently, flexible flat display devices, which are lightweight and resistant to impact, have been developed by utilizing a base film made of a material such as plastic.

Different flexible flat display devices may include, for example, organic light emitting diode display elements, liquid crystal display elements, and electrophoretic display (EPD) elements, among others.

In addition, flexible flat display devices may include thin film transistors (TFTs). With advantages such as having good carrier mobility, a low temperature polysilicon (LTPS) TFT can be applicable to a high speed operational circuit and can be used for a CMOS circuit, so LTPS TFTS are commonly utilized from among various types of thin film transistors.

The LTPS TFT includes a polysilicon layer formed by crystallizing an amorphous silicon layer. Methods for crystallizing the amorphous silicon layer include, for example, solid phase crystallization, excimer laser crystallization, and crystallization using a metal catalyst. The excimer laser crystallization method has been widely used because it allows for low temperature processes, so that a thermal effect on a substrate is relatively low and a polysilicon layer having relatively excellent carrier mobility over 100 cm2/Vs can be made.

However, when the crystallization process is performed using a laser on a base film made of plastic, laser beams passed through the polysilicon layer are partially absorbed by the base film, thereby causing deterioration of the base film. Such a deterioration of the base film not only causes a negative effect on product reliability, but also causes failures such as separation of the base film.

The above information disclosed in this Background section is only for enhancement of understanding of the background of the described technology, and therefore, it may contain information that does not form the prior art that is already known in this country to a person of ordinary skill in the art.

### SUMMARY OF THE INVENTION

The described technology has been made in an effort to provide a display device that can stably form an active layer crystallized using a laser on a base film including a material such as plastic.

A display device according to an exemplary embodiment includes: a base film including plastic; an active layer on the base film, the active layer including a polysilicon layer formed by crystallizing an amorphous silicon layer using a laser; a barrier layer between the active layer and the base film; and a laser absorption layer between the barrier layer and the active layer.

The barrier layer may include a plurality of inorganic layers.

The display device may further include a buffer layer between the laser absorption layer and the active layer.

The laser absorption layer may include an amorphous silicon layer.

The active layer may be crystallized through excimer laser annealing (ELA),

The base film may include a material including polyimide.

The barrier layer may include a structure in which silicon oxide layers and silicon nitride layers are alternately layered.

The buffer layer may include at least one of a tetra ethyl ortho silicate (TEOS) layer, a silicon nitride layer, a silicon oxide layer, and a silicon oxynitride layer.

The base film, the barrier layer, the laser absorption layer, and the active layer may be flexible.

A display device according to another exemplary embodiment includes: a base film including plastic; an active layer on the base film, the active layer including a polysilicon layer formed by crystallizing an amorphous silicon layer using a laser; a barrier layer between the active layer and the base film, the barrier layer including a plurality of inorganic layers; and a laser absorption layer between two of the plurality of inorganic layers.

The display device may further include a buffer layer between the barrier layer and the active layer.

According to exemplary embodiments of the present invention, a display can have a stably formed active layer crystallized using a laser on a base film including a material such as plastic.

### BRIEF DESCRIPTION OF THE DRAWINGS

FIG. 1 is a cross-sectional view of a display device according to a first exemplary embodiment;

FIG. 2 is an enlarged cross-sectional view of a portion of FIG. 1;

FIG. 3 is a cross-sectional view of a display device according to a second exemplary embodiment; and

FIG. 4 is an enlarged cross-sectional view of a portion of FIG. 3.

Description of Symbols

| | |
|---|---|
| 20: thin film transistor | 70: organic light emitting element |
| 100: base film | 101, 102: display device |
| 110: barrier layer | 120: buffer layer |
| 132: active layer | 140: gate insulating layer |
| 160: interlayer insulating layer | 190: pixel defining layer |
| 200: laser absorption layer | 300: thin film encapsulation layer |

### DETAILED DESCRIPTION OF THE EMBODIMENTS

The present invention will be described more fully hereinafter with reference to the accompanying drawings, in which exemplary embodiments of the invention are shown. As those skilled in the art will recognize, the described embodiments may be modified in various different ways without departing from the spirit or scope of the present invention.

Elements having the same or similar structures throughout the embodiments are denoted by the same reference numerals and are described in detail for a first exemplary embodiment. In subsequent exemplary embodiments, only the elements other than the same or similar elements will be described.

The drawings are schematic and not proportionally scaled. Relative scales and ratios in the drawings are enlarged or reduced for the purpose of convenience, and the scales may be random and the invention should not be limited thereto. In addition, it will be understood that when an element is referred to as being “on” another element, it can be directly on the other element, or one or more intervening elements may be present therebetween.

The embodiments described represent ideal exemplary embodiments in detail. Therefore, various modifications from diagrams are to be expected. Accordingly, the exemplary embodiments should not be limited to the specific shapes of shown regions, and may for example, also include modifications or variations in the shapes by manufacturing.

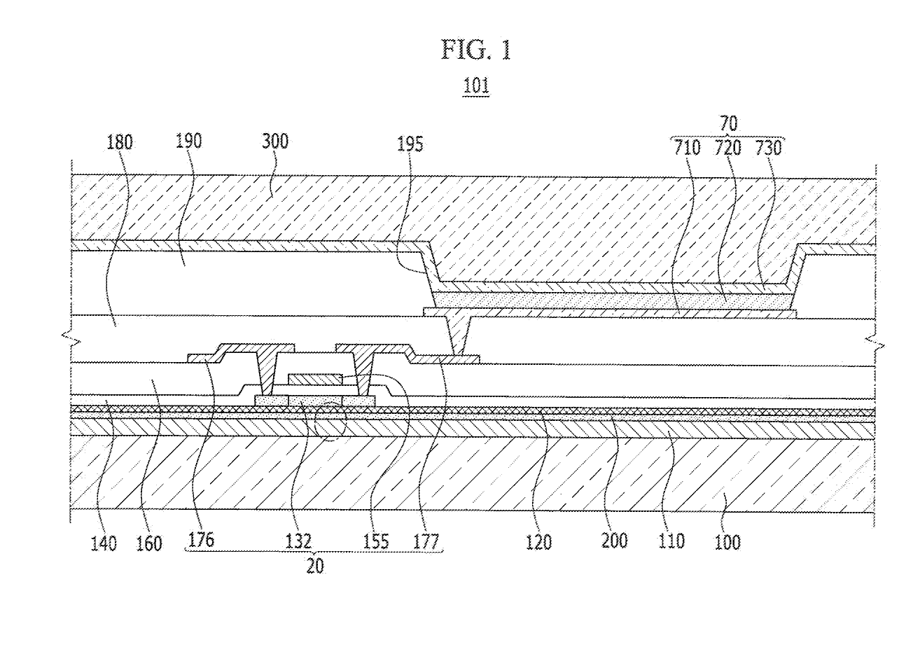

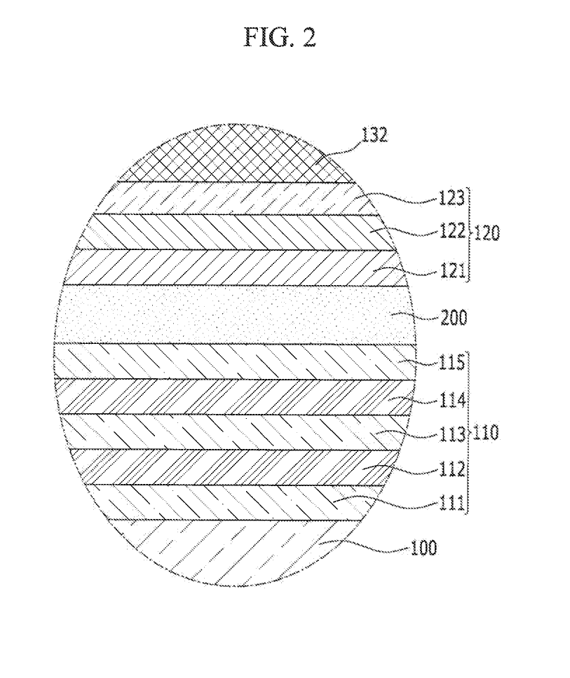

Hereinafter, a display device 101 according to a first exemplary embodiment will be described with reference to FIG. 1 and FIG. 2.

As shown in FIG. 1, the display device 101 according to the first exemplary embodiment includes a base film 100, a barrier layer 110, a laser absorption layer 200, a thin film transistor 20, and an organic light emitting element 70.

The thin film transistor 20 includes an active layer 132, a gate electrode 155, a source electrode 176, and a drain electrode 177. In the first exemplary embodiment, the thin film transistor 20 has a top gate structure in which the gate electrode 155 is disposed on the active layer 132.

The active layer 132 includes a polysilicon layer crystallized from an amorphous silicon layer using a laser. The crystallization method using a laser may be, for example, an excimer laser annealing (ELA) method in particular.

In addition, the display device 101 may further include a gate insulating layer 140 for insulating the active layer 132 of the thin film transistor 20 from the gate electrode 155 and an interlayer insulating layer 160 for insulating the gate electrode 155 from the source electrode 176 and the drain electrode 177.

The organic light emitting element 70 includes a pixel electrode 710 connected to the drain electrode 177 of the thin film transistor 20, an organic emission layer 720 on the pixel electrode 710, and a common electrode 730 on the organic emission layer 720. Here, the pixel electrode 710 is a positive (+) electrode, which is a hole injection electrode and the common electrode 730 is a negative (−) electrode, which is an electron injection electrode. However, the first exemplary embodiment is not limited thereto, and for example, the pixel electrode 710 may be the negative electrode and the common electrode 730 may be the positive electrode, according to a particular driving method of the display device 101.

Holes from the pixel electrode 710 and electrons from the common electrode 730 are injected into the organic emission layer 720, and light emission occurs when excitons, which are combinations of holes and electrons, drop from an excited state to a ground state.

The display device 101 may further include a pixel defining layer 190 having an opening 195 exposing the pixel electrode 710 to define a light emission area. The organic emission layer 720 is positioned on the pixel electrode 710 in the opening 195 of the pixel defining layer 190.

In addition, the display device 101 may further include an additional insulating layer 180 for insulating the pixel electrode 710 from the source electrode 176. The additional insulating layer 180 may have a planarization or planarizing characteristic, so that it can make the organic emission layer 720 substantially uniformly disposed on the pixel electrode 710.

Further, in the display device 101 according to the first exemplary embodiment, the structure of the organic light emitting element 70 and the thin film transistor 20 are not limited to the structures shown in FIG. 2. The structures of the organic light emitting element 70 and the thin film transistor 20 may be changed in a variety of ways and can be easily modified by a person skilled in the art.

The base film 100 is made of or includes a plastic. Particularly, the base film 100 may be made of polyimide having excellent heat resistance, chemical resistance, durability, and electric insulation. However, the first exemplary embodiment is not limited thereto, and the base film 100 may be made of, for example, polyethylene etherphtalate, polyethylene naphthalate, polycarbonate, polyarylate, polyetherimide, or polyethersulfone.

The barrier layer 110 prevents permeation of moisture or oxygen. The base film 100 made of plastic is more permeable to moisture or oxygen than a substrate made of glass. Thus, the barrier layer 110 is positioned on the base film 100 to prevent or reduce moisture or oxygen from permeating past the base film 100 and negatively affecting the organic light emitting element 70 on the base film 100.

As shown in FIG. 2, the barrier layer 110 includes a plurality of inorganic layers 111, 112, 113, 114, and 115. Particularly, the barrier layer 110 has a structure in which silicon oxide layers 111, 113, and 115 and silicon nitride layers 112 and 114 are alternately stacked. However, the first exemplary embodiment is not limited thereto, and the barrier layer 110 may include various different types of inorganic layers.

A laser absorption layer 200 prevents or reduces parts of laser beams radiated during a process of forming the active layer 132 of the thin film transistor 20 from passing through the barrier layer 110 toward the base film 100. If the laser beams reach the base film 100, the laser beams can be absorbed by the base film 100, which may deteriorate the base film 100. Therefore, the laser absorption layer 200 prevents the laser beams from reaching the base film 100 by absorbing the laser beams moving toward the base film 100.

In the first exemplary embodiment, an amorphous silicon layer may be used as the laser absorption layer 200. The amorphous silicon layer used as the laser absorption layer 200 can be partially crystallized while absorbing the laser beams.

The buffer layer 120 is arranged on the laser absorption layer 200. The buffer layer 120 includes at least one of a tetra ethyl ortho silicate (TEOS) layer, a silicon nitride layer, a silicon oxide layer, or a silicon oxynitride layer. FIG. 2 illustrates a tri-layered buffer layer 120 that includes a silicon nitride layer 121, a silicon oxide layer 122, and a TEOS layer 123.

Meanwhile, the buffer layer 120 may be omitted in the display device 101 in some embodiments. However, the buffer layer 120 additionally blocks moisture or oxygen that passed through the barrier layer 110, and also planarizes the surface to stably form the active layer 132.

The active layer 132 of the thin film transistor 20 is disposed on the buffer layer 120. As described above, the active layer 132 is formed by patterning the polysilicon layer that is formed by crystallizing the amorphous silicon layer using a laser.

In addition, as shown in FIG. 1, the display device 101 may further include a thin film encapsulation layer 300 covering the organic light emitting element 70. The thin film encapsulation layer 300 may have a structure in which at least one of a plurality of inorganic layers and at least one of a plurality of organic layers are layered. Like the base film 100 and the barrier layer 110, the thin film encapsulation layer 300 prevents or reduces permeation of moisture or oxygen into the organic light emitting element 70 while protecting the organic light emitting element 70.

In addition, in the first exemplary embodiment, the display device 101 is not limited to an organic light emitting diode display. Thus, the first exemplary embodiment can be applied to any display device that includes a thin film transistor using a polysilicon layer crystallized by a laser. Such display devices include, for example, liquid crystal displays and electrophoretic display (EPD) devices.

With such a configuration, the display device 101 according to the first exemplary embodiment can stably form an active layer 132 crystallized using a laser, on a base film 100 made of or including plastic. That is, separation of the base film 100 from a barrier layer 110 caused by deterioration of the base film 100 due to the laser beams during the forming of the active layer 132 can be effectively prevented or reduced.

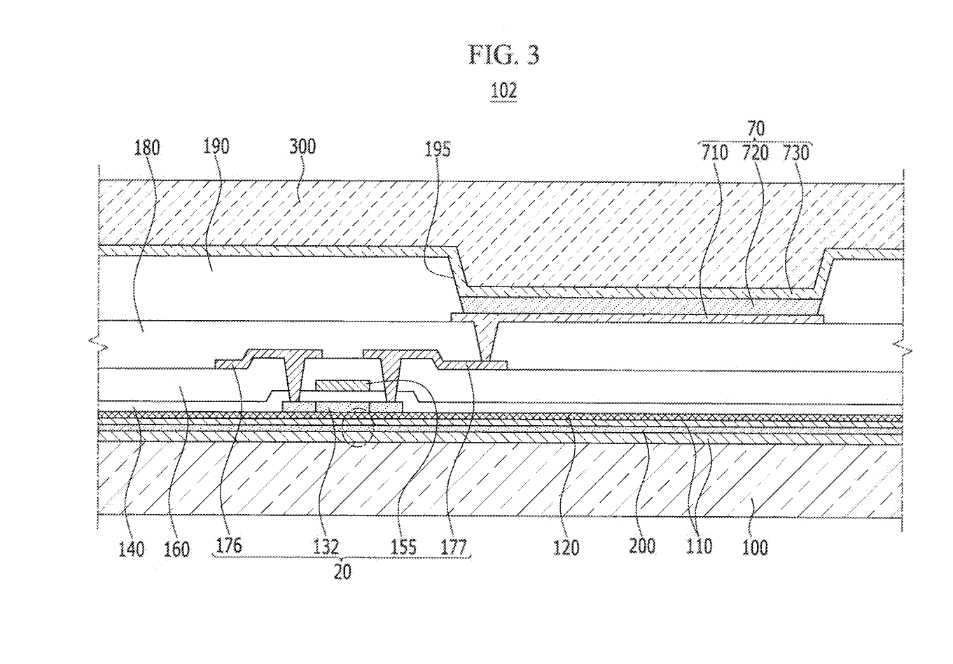

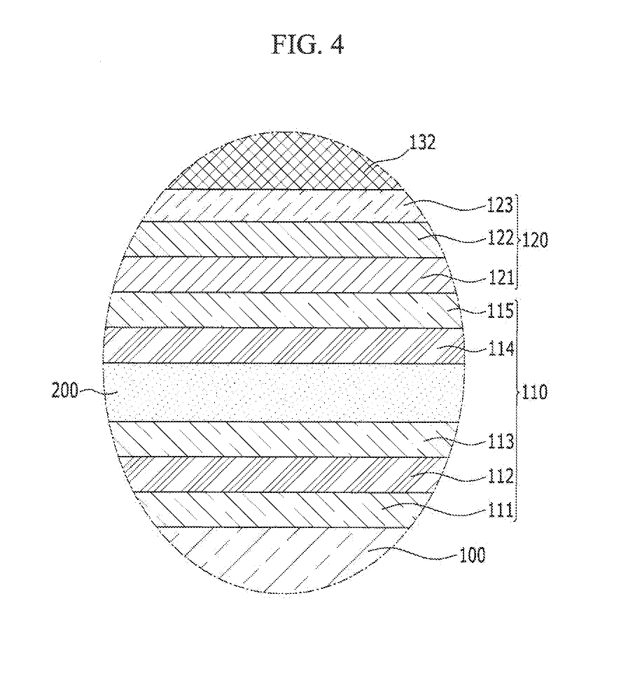

Hereinafter, a display device 102 according to a second exemplary embodiment will be described with reference to FIG. 3 and FIG. 4.

As shown in FIG. 3, in the display device 102 according to the second exemplary embodiment, a laser absorption layer 200 is disposed in the middle of a barrier layer 110.

Particularly, as shown in FIG. 4, the laser absorption layer 200 is positioned between a plurality of inorganic layers 111, 112, 113, 114, and 115 of the barrier layer 110. The barrier layer 110 includes silicon oxide layers 111, 113, and 115 and silicon nitride layers 112 and 114 that are alternately stacked, and the laser absorption layer 200 may be positioned in at least one space between the silicon oxide layers 111, 113, and 115 the silicon nitride layers 112 and 114.

With such a configuration, the display device 102 according to the second exemplary embodiment can also stably form the active layer 132 crystallized using a laser beam, on a base film 100 made of or including plastic. That is, separation of the base film 100 from the barrier layer 110 caused by deterioration of the base film 100 due to the laser beams during the forming of the active layer 132 can be effectively prevented or reduced.

While this disclosure has been described in connection with what is presently considered to be practical exemplary embodiments, it is to be understood that the invention is not limited to the disclosed embodiments, but is instead intended to cover various modifications and equivalent arrangements included within the spirit and scope of the appended claims.

What is claimed is:

1. A display device comprising:
a base film comprising plastic;
an active layer on the base film, the active layer comprising a polysilicon layer formed by crystallizing an amorphous silicon layer using a laser;
a barrier layer between the active layer and the base film; and
a laser absorption layer between the barrier layer and the active layer.

2. The display device of claim 1, wherein the barrier layer comprises a plurality of inorganic layers.

3. The display device of claim 1, further comprising a buffer layer between the laser absorption layer and the active layer.

4. The display device of claim 1, wherein the laser absorption layer comprises an amorphous silicon layer.

5. The display device of claim 4, wherein the active layer is crystallized through excimer laser annealing (ELA).

6. The display device of claim 4, wherein the base film comprises a material including polyimide.

7. The display device of claim 4, wherein the barrier layer comprises a structure in which silicon oxide layers and silicon nitride layers are alternately stacked.

8. The display device of claim 4, wherein the buffer layer comprises at least one of a tetra ethyl ortho silicate (TEOS) layer, a silicon nitride layer, a silicon oxide layer, or a silicon oxynitride layer.

9. The display device of claim 4, wherein the base film, the barrier layer, the laser absorption layer, and the active layer are flexible.

10. A display device comprising:
a base film comprising plastic;
an active layer on the base film, the active layer comprising a polysilicon layer formed by crystallizing an amorphous silicon layer using a laser;
a barrier layer between the active layer and the base film, the barrier layer comprising a plurality of inorganic layers; and
a laser absorption layer between two of the plurality of inorganic layers.

11. The display device of claim 10, further comprising a buffer layer between the barrier layer and the active layer.
